(19) United States
(12) Patent Application Publication
(10) Pub. No.: US 2025/0364707 A1
(43) Pub. Date: Nov. 27, 2025

(54) ENERGY STORAGE DEVICE AND STATE DETECTION METHOD FOR ENERGY STORAGE DEVICE

(71) Applicant: Panasonic Intellectual Property Management Co., Ltd., Osaka (JP)

(72) Inventors: Shunya IGARASHI, Osaka (JP); Toshitaka KOBAYASHI, Osaka (JP)

(73) Assignee: Panasonic Intellectual Property Management Co., Ltd., Osaka (JP)

(21) Appl. No.: 18/994,977

(22) PCT Filed: Jul. 21, 2023
(86) PCT No.: PCT/JP2023/026702

§ 371 Date: Jan. 15, 2025

(30) Foreign Application Priority Data
Jul. 22, 2022 (JP) 2022-117424

(51) Int. Cl. H01M 50/578; G01R 31/36; G01R 31/389; H01G 11/24; H01G 11/70; H01G 11/80; H01M 50/107; H01M 50/186; H01M 50/533; H01M 50/566

(52) U.S. Cl. CPC H01M 50/578; G01R 31/3644; G01R 31/389; H01G 11/24; H01G 11/70; H01G 11/80; H01M 50/107; H01M 50/186; H01M 50/533; H01M 50/566

(57) ABSTRACT

A power storage device includes a power storage element, a case having a bottomed cylindrical shape with an opening at one end, and housing the power storage element, a sealing member sealing the opening, and a current collecting plate. The current collecting plate has a first region electrically connected to an external terminal that the sealing member or the case has, a second region joined to the power storage element, at least one first conductive part linking the first region to the second region, and at least one second conductive part linking the first region to the second region. The electrical resistance of the first conductive part is different from the electrical resistance of the second conductive part.

### TECHNICAL FIELD

The present disclosure relates to a power storage device and a state detection method for a power storage device.

### BACKGROUND ART

With increasing demand for in-vehicle use, etc., it has been required for power storage devices, such as secondary batteries, to have higher output and higher capacity.

As a current collecting structure for obtaining high output, a so-called end face current collecting structure has been studied, in which a negative or positive electrode current collector-exposed portion protruded from the end face of a wound electrode group is welded to a current collecting plate.

As an example of a power storage device having an end face current collecting structure, for example, Patent Literature 1 discloses a power storage apparatus including: a power storage element having a first electrode and a second electrode, and having a first end from which the first electrode is drawn out; an electrolyte impregnated in the power storage element; a terminal plate having an element connection portion electrically connected to the first electrode at the first end and an external terminal portion connected to the element connection portion; an outer body having a tubular shape with an opening, and housing the power storage element, together with the electrolyte solution; and a sealing member having an insertion hole for inserting the external terminal portion thereinto, and sealing the opening of the outer body, together with the external terminal portion. The external terminal portion is a columnar body or a tubular body having a tapered portion around the outer periphery at its tip end. In the direction extending from the bottom of the outer body to the opening, the end sides of the side wall at the opening of the outer body are positioned between both ends of the tapered portion.

Patent Literature 2 discloses a cylindrical secondary battery including an electrode plate group formed by winding a positive electrode plate and a negative electrode plate, with a separator interposed therebetween, and a metal outer can that houses the electrode plate group, together with an electrolyte solution. At least one of the positive electrode plate and the negative electrode plate has, at an end thereof along its longitudinal direction, a core material exposed portion. The core material exposed portion of either the positive electrode plate or the negative electrode plate protrudes on at least one of the upper and lower surfaces of the electrode plate group, so that the tip end of the protruding portion itself forms a flat portion. A current collecting plate is joined to the flat portion. The current collecting plate comprises a fixed portion joined to the flat portion and a movable portion joined to the bottom of the outer can. Part of the movable portion includes an outer peripheral surface of the current collecting plate.

### CITATION LIST

### Patent Literature

Patent Literature 1: Domestic re-publication of PCT international application No. 2013-088724
Patent Literature 2: Japanese Laid-Open Patent Publication No. 2004-139777

### SUMMARY OF INVENTION

### Technical Problem

In a power storage device having an end face current collecting structure, when the internal pressure in the device rises, the sealing member and the case are subjected to pressure and deform so as to bulge, and the current collecting plate also deforms along with the deformation of the sealing member and the case. At this time, along with the deformation of the current collecting plate, the joint spot between the power storage element and the current collecting plate may be peeled off, and the current collecting performance may be lowered in some cases.

The higher the capacity and the output of the power storage device are, the greater the amount of gas generated in the event of abnormal heat generation is, and the more the internal pressure tends to rise. By using the current collecting plate disclosed in Patent Literature 2, it is possible to suppress the peeling-off of the joint spot with the current collecting plate, against external vibrations and impacts, but this is insufficient for the purpose of suppressing the peeling-off of the joint spot against the deformation of the current collecting plate caused by the internal pressure rise. Moreover, with the current collecting plate disclosed in Patent Literature 2, due to a movable portion provided therein, the path for current to flow through the current collecting plate is long even in the normal use, and the internal resistance increases.

### Solution to Problem

One aspect of the present disclosure relates to a power storage device, including: a power storage element; a case having a bottomed cylindrical shape with an opening at one end, and housing the power storage element; a sealing member sealing the opening; and a current collecting plate, wherein the current collecting plate has a first region electrically connected to an external terminal that the sealing member or the case has, a second region joined to the power storage element, at least one first conductive part linking the first region to the second region, and at least one second conductive part linking the first region to the second region, and an electrical resistance of the first conductive part is different from an electrical resistance of the second conductive part.

Another aspect of the present disclosure relates to a power storage device, including: a power storage element; a case having a bottomed cylindrical shape with an opening at one end, and housing the power storage element; a sealing member sealing the opening; and a current collecting plate, wherein the current collecting plate has a first region electrically connected to an external terminal that the sealing member or the case has, a second region joined to the power storage element, at least one first conductive part linking the first region to the second region, and at least one second conductive part linking the first region to the second region, and when an internal pressure in the case exceeds a predetermined first pressure, at least part of the first conductive part of the current collecting plate breaks, and the second conductive part remains unbroken.

Yet another aspect of the present disclosure relates to a state detection method for a power storage device, the method including, in the above-described power storage device, detecting a state of the power storage device by detecting a change in electrical characteristics of the power storage device caused by the breakage of the first conductive part.

### Advantageous Effects of Invention

Even when the internal pressure of the power storage device rises, it is possible to suppress the peeling-off of the joint between the power storage element and the current collecting plate along with the deformation of the current collecting plate. Furthermore, it is possible to detect a change in the state of the power storage device due to the rise in internal pressure, in a simple and convenient way.

While the novel features of the invention are set forth particularly in the appended claims, the invention, both as to organization and content, will be better understood and appreciated, along with other objects and features thereof, from the following detailed description taken in conjunction with the drawings.

### BRIEF DESCRIPTION OF DRAWINGS

FIG. 1A A top view showing the appearance of a current collecting plate according to an embodiment of the present disclosure.

FIG. 1B An oblique view showing the appearance of the current collecting plate according to an embodiment of the present disclosure.

FIG. 2 An oblique view showing, in the current collecting plate shown in FIGS. 1A and 1B, the appearance of the current collecting plate when the internal case pressure exceeds a first pressure and a first conductive part has broken.

FIG. 3A A top view of another example of a current collecting plate according to an embodiment of the present disclosure.

FIG. 3B An oblique of the example of the current collecting plate according to an embodiment of the present disclosure.

FIG. 4 An oblique view showing, in the current collecting plate shown in FIGS. 3A and 3B, the appearance of the current collecting plate when the internal case pressure exceeds a first pressure and a first conductive part has broken.

FIG. 5 A longitudinal sectional view showing the configuration of a power storage device according to an embodiment of the present disclosure.

### DESCRIPTION OF EMBODIMENTS

### [Power Storage Device]

Embodiments of a power storage device according to the present disclosure will be described below by way of examples, but the present disclosure is not limited to the examples described below. In the following description, specific numerical values and materials are exemplified in some cases, but other numerical values and other materials may be adopted as long as the effects of the present disclosure can be obtained. In the present specification, when referring to “a range of a numerical value A to a numerical value B,” the range includes the numerical value A and the numerical value B, and can be rephrased as “a numerical value A or more and a numerical value B or less.” In the following description, when the lower and upper limits of numerical values related to specific physical properties, conditions, etc. are mentioned as examples, any one of the mentioned lower limits and any one of the mentioned upper limits can be combined in any combination as long as the lower limit is not equal to or more than the upper limit. When a plurality of materials are mentioned as examples, one kind of them may be selected and used singly, or two or more kinds of them may be used in combination.

The present disclosure encompasses a combination of matters recited in any two or more claims selected from plural claims in the appended claims. In other words, as long as no technical contradiction arises, matters recited in any two or more claims selected from plural claims in the appended claims can be combined.

A power storage device according to one embodiment of the present disclosure includes a power storage element, a case having a bottomed cylindrical shape with an opening at one end and housing the power storage element, a sealing member sealing the opening, and a current collecting plate. The current collecting plate has a first region electrically connected to an external terminal that the sealing member or the case has, and a second region joined to the power storage element.

The current collecting plate further includes at least one first conductive part linking the first region to the second region, and at least one second conductive part linking the first region to the second region. The first conductive part and the second conductive part each independently form at least two conductive paths through each of which current flows between the position electrically connected with the external terminal in the first region and the position joined with the power storage element in the second region. In the normal state of the power storage device, current flows in parallel through both the conductive paths (first conductive paths) via the first conductive part and the conductive paths (second conductive paths) via the second conductive part.

When the internal pressure of the power storage device rises due to abnormal discharge or the like, the central portion of the current collecting plate deforms so as to bulge toward the external terminal and move away from the power storage element. At this time, the joint between the current collecting plate and the power storage element in the second region may be peeled off in some cases due to the deformation. Such peeling-off of the joint may occur even with an internal pressure lower than the valve operating pressure of the power storage device.

In one embodiment of the power storage device of the present disclosure, the power storage device is configured such that at least one of the at least one first conductive part breaks when the internal pressure in the case exceeds a predetermined first pressure. On the other hand, the second conductive part remains unbroken even when the internal pressure exceeds a first pressure. In other words, when the internal pressure exceeds the first pressure, the first conductive paths via the first conductive part between the first region and the second region are cut off, and current flows through the second conductive paths via the second conductive part between the first region and the second region. By detecting a resulting change in electrical characteristics (e.g., a change in internal resistance of the device), the state of the power storage device can be detected. Also, this configuration can suppress the joint with the power storage element in the second region from being peeled off due to the deformation of the current collecting plate.

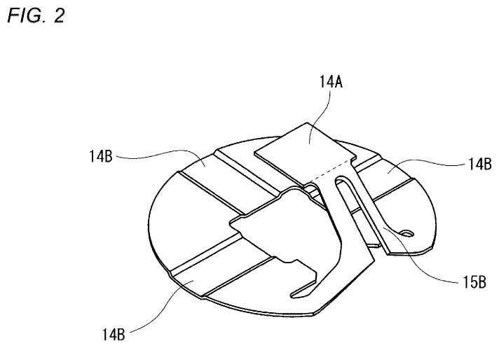

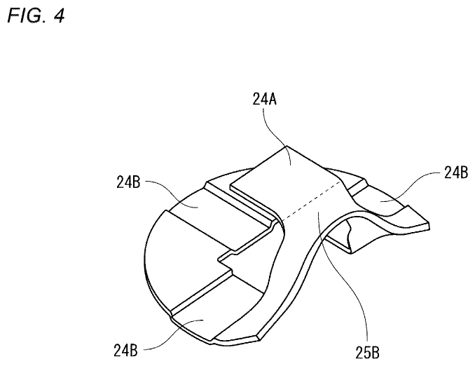

When the internal pressure in the case exceeds the first pressure, the second conductive part can deform such that the first region protrudes toward the external terminal (so as to move away from the power storage element) in the axial direction of the case, in association with the breakage of the first conductive part (see FIGS. 2 and 4). This suppresses the deformation of the second region, and suppress the peeling-off of the joint with the power storage element along with the deformation of the current collecting plate.

The electrical resistance of the first conductive part is different from the electrical resistance of the second conductive part. In order to reduce the internal resistance of the device in the normal state where the internal pressure in the case is equal to or lower than the first pressure, it is preferable that the electrical resistance of the first conductive part is lower than that of the second conductive part.

In order to set the electrical resistance of the first conductive part to be lower than that of the second conductive part, the length of the first conductive part may be set shorter than that of the second conductive part. On the other hand, in order to allow the first conductive part to more easily break with increase in the internal pressure in the case than the second conductive part, the first conductive part may be formed to have a narrower minimum width than the minimum width of the second conductive part.

Here, the length of the first conductive part and the length of the second conductive part respectively mean the shortest length or the average length along the first conductive paths and that along the second conductive paths. When the first conductive path and/or the second conductive path form a curved or bent path, the length of the first conductive part and the length of the second conductive part each refer to the shortest total length or the average total length along the curved or bent path. The width of the first conductive part and the width of the second conductive part respectively mean the length in the direction perpendicular to the direction along the first conductive path and that perpendicular to the direction along the second conductive path.

As an example of the configuration of the current collecting plate having a first conductive part and a second conductive part, a plurality of slits (openings or through-holes) may be intermittently formed along the contour of the first region. The slits separate the first region from the second region. For example, a region sandwiched between the lengthwise ends of the plurality of slits links the first region to the second region with a minimum width, and can form the first conductive part. No slit is formed along a part of the contour of the first region, and the part of the contour of the first region where no slit is formed (the part not constituting the minimum width) is continuous with the second conductive part.

The first region includes, for example, the central portion of the current collecting plate. In this case, the second region is provided in the outer peripheral portion outside the central portion. The first conductive part and the second conductive part, at different positions in the circumferential direction, each link between the first region in the central portion and the second region provided in the outer peripheral portion. The first conductive part can link between the central portion and the outer peripheral portion so as to form a conductive path that links the central portion to the outer peripheral portion over a short distance. At this time, the second conductive part forms another conductive path that flows in a detour between the first region and the second region, independent of the conductive path that passes the first conductive part.

The power storage element is, for example, a columnar wound body formed by winding a positive electrode and a negative electrode, with a separator interposed therebetween. The wound body (power storage element) can be housed in the case such that one end face of the wound body faces the bottom of the case and the other end face faces the sealing member on the opening side of the case. The opening of the case is closed, with the wound body housed therein, and is maintained airtight. The method for sealing the opening of the case is not particularly limited, and a known method can be used.

The above-described current collecting plate having a first conductive part and a second conductive part may be joined to one end face of the wound body, so as to be joined to the electrode exposed at the one end face in the second region, and electrically connected to a terminal portion of the sealing member in the first region. The above-described current collecting plate having a first conductive part and a second conductive part may be joined to the other end face of the wound body, so as to be joined to the electrode exposed at the other end face in the second region, and electrically connected to the case bottom in the first region. The power storage device may include a pair of current collecting plates including a current collecting plate joined to one end face of the wound body and a current collecting plate joined to the other end face of the wound body. One of the pair of current collecting plates may be the above-described current collecting plate having a first conductive part and a second conductive part. Both of the pair of current collecting plates may be the above-described current collecting plate having a first conductive part and a second conductive part. In the following, a current collecting plate which is the above-described current collecting plate having a first conductive part and a second conductive part and is joined to one end face of the wound body and electrically connected to the terminal portion of the sealing member is sometimes referred to as a first current collecting plate. A current collecting plate which is the above-described current collecting plate having a first conductive part and a second conductive part and is joined to the other end face of the wound body and electrically connected to the bottom of the case is sometimes referred to as a second current collecting plate.

The current collecting plate has two principal surfaces. In this case, a first principal surface of the current collecting plate faces the sealing member or the bottom of the case, while a second principal surface of the current collecting plate faces the end face of the wound body. In order to easily form a joint with the power storage element, the second region of the current collecting plate may be configured to protrude on the second principal surface side. The first region of the current collecting plate maybe configured to protrude on the first principal surface side.

In the first current collecting plate, the first region may be electrically connected to a terminal portion of the sealing member, while the second region may be joined to a first electrode of the power storage element. In this case, the first region may be joined to the terminal portion by welding. The second region may be joined to the first electrode of the power storage element by welding.

In the second current collecting plate, the first region may be electrically connected to the case, while the second region may be joined to a second electrode of the power storage element. The second region may be joined to the second electrode of the power storage element by welding.

Of the first electrode and the second electrode, one is a positive electrode, and the other is a negative electrode. Depending on the configuration of the power storage device, the current collecting plate may be electrically connected to the positive electrode or the negative electrode. That is, the current collecting plate may be a positive electrode current collecting plate or a negative electrode current collecting plate. The first current collecting plate electrically connected to the terminal portion of the sealing member may be electrically connected to the positive electrode, while the second current collecting plate electrically connected to the case may be electrically connected to the negative electrode. The first current collecting plate electrically connected to the terminal portion of the sealing member may be electrically connected to the negative electrode, and the second current collecting plate electrically connected to the case may be electrically connected to the positive electrode.

When the power storage device includes a first current collecting plate and a second current collecting plate, the first and second current collecting plates may have the same configuration or different configurations. The first and second current collecting plates may be different in the shape of at least one of the first conductive part and the second conductive part. The first and second current collecting plates may be different in characteristics, such as the threshold of internal pressure (first pressure) at which the first conductive part breaks, the resistance value when the first conductive part has broken, and the resonance frequency.

In the current collecting plate, when the internal pressure in the case exceeds the first pressure, as described above, the second conductive part deforms in association with the breakage of the first conductive part, and the first region protrudes toward the external terminal (so as to move away from the power storage element) in the axial direction of the case. At this time, in the deformed current collecting plate, the second conductive part acts as a spring against vibrations in the axial direction, and the power storage element tends to readily vibrate in the axial direction in response to external force, which may cause the vibration resistance of the power storage device to be lowered. In order to maintain the vibration resistance of the power storage device high, it is preferable to maintain the resonance frequency of the power storage device at, for example, 500 Hz or higher.

The spring constant of the first current collecting plate against vibrations in the axial direction when the first conductive part has broken is denoted by k₁. The spring constant of the second current collecting plate against vibrations in the axial direction when the first conductive part has broken is denoted by k₂. A resonance frequency fₙ of the power storage device is given by the following equation, where M represents the mass of the power storage element.

$${f}_{n} = {( ( {k}_{1} + {k}_{2} ) / M )}^{1 / 2} / 2 π$$

For example, when the second conductive part is designed as a flat spring with both ends fixed, the spring constant k (k₁ or k₂) is given by the following equation.

$$k = 192 EI / {L}^{3}$$

E: Young's modulus

$$I : area moment of inertia ( = {bh}^{3} / 12 )$$

L: length of second conductive part
b: width of second conductive part
h: thickness of second conductive part

In the above equation, the spring constants k₁ and k₂ can be calculated by a numerical simulation that takes into account the material (elastic constant) and the shape of the current collecting plate. The resonant frequency fₙ of the power storage device can also be calculated by a numerical simulation. As the software for the numerical simulation, ANSYS is used, for example.

In the power storage device, as comparted to the second current collecting plate facing the bottom of the case, the first current collecting plate facing the sealing member is more susceptible to deform so as to bulge when the internal pressure in the case rises, and the joint with the power storage element tends to be more easily peeled off due to the deformation of the current collecting plate. Therefore, it is more necessary to suppress the peeling-off of the joint with the power storage element in the first current collecting plate than in the second current collecting plate. In light of this, the shape of the second conductive part of the first current collecting plate may be designed so that when the first conductive part has broken, the deformation can easily occur, such that the first region of the first current collecting plate protrude toward the sealing member (so as to move away from the power storage element) relative to the second region. However, as the second conductive part is designed to have a shape more susceptible to the protruding deformation, the spring constant k₁ tends to be smaller, and the resonant frequency fₙ tend to be smaller. It is therefore preferable to set k₂>k₁ so that the resonant frequency fₙ can be maintained high.

The above-described current collecting plate (first current collecting plate and second current collecting plate) having a first conductive part and a second conductive part can be adopted in the structure of any power storage device, regardless of whether it is a primary battery or a secondary battery and without depending on the configuration of the positive electrode and the negative electrode. The power storage device according to one embodiment of the present disclosure is suitable to be configured as, for example, a nonaqueous electrolyte secondary battery, an alkaline storage battery, or a capacitor, and contributes to increasing the output of nonaqueous electrolyte batteries. Nonaqueous electrolyte batteries include lithium-ion secondary batteries and all-solid-state batteries.

The power storage device according to one embodiment of the present disclosure will be specifically below with reference to the drawings, using as an example the case of being used in a lithium-ion secondary battery which is one example of the power storage device.

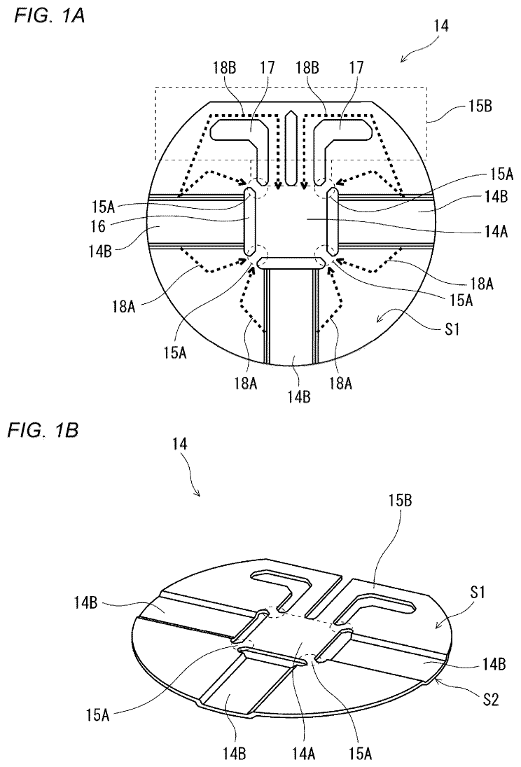

FIGS. 1A and 1B show an example of the configuration of a current collecting plate according to an embodiment of the present disclosure. FIG. 1A is a top view showing the appearance of a current collecting plate 14, and FIG. 1B is an oblique view of the current collecting plate 14 as viewed from the first principal surface side (the surface opposite to the surface where a joint with the power storage element is formed). In a preferred embodiment, the current collecting plate 14 is disposed between the power storage element and the sealing member, and can be used to electrically connect one of the electrodes (first electrode) of the power storage element to the terminal portion of the sealing member. The current collecting plate 14 may be a first current collecting plate or a positive electrode current collecting plate.

The current collecting plate 14 has a first principal surface S1 and a second principal surface S2 opposite to the first principal surface S1. The current collecting plate 40 is, for example, a metal plate, which can be punched into a predetermined shape and then processed into a shape having protrusions and recesses by press molding. In the example of FIGS. 1A and 1B, the approximate shape of the current collecting plate 14 is a disc, but in order to form a first conductive part and a second conductive part, a through-hole or a notch is formed in a partial region. The first principal surface S1 faces the sealing member or the bottom of the case in the manufactured power storage device. The second principal surface S2 faces the power storage element in the manufactured power storage device.

The current collecting plate 14 has a first region 14A in its central portion and a second region 14B in its outer peripheral portion outside the first region 14A. When the current collecting plate is placed within the case, for example, the first region 14A is located at the center of the case or the center of the power storage element, and the second region 14B extends from the center toward the tubular portion of the case. A plurality of the second regions 14B, while spaced apart from each other, may extend radially along the radial direction so as to move away the first region 14A in the center.

The first region 14A is, on the first principal surface S1 side thereof, electrically connected to an external terminal that the sealing member or the case has. The second regions 14B are, on the second principal surface S2 side thereof, joined to the power storage element. As shown in the example of FIG. 1B, the second regions 14B may be configured to protrude on the second principal surface S2 side, for easy formation of a joint with the power storage element. Likewise, the first region 14A may be configured to protrude on the first principal surface S1 side, for easy electrical connection with the external terminal.

First conductive parts 15A each link between the first region 14A and the second region 14B. In the example of FIGS. 1A and 1B, the first conductive parts 15A are each a region of minimum width sandwiched between the lengthwise ends of a plurality of slits 16 formed along the contour of the first region 14A.

A second conductive part 15B, like the first conductive parts 15A, links between the first region 14A and the second region 14B. The first conductive parts 15A form first conductive paths 18A linking between the first region 14A and the second region 14B, and the second conductive part 15B forms second conductive paths 18B linking between the first region 14A and the second region 14B. In FIG. 1A, the first conductive paths 18A and the second conductive paths 18B are each indicated by an arrow directed from the second region 14B to the first region 14A.

The first conductive paths 18A and the second conductive paths 18B each independently form current flow paths, and in the normal state where the first conductive parts 15A have not broken (the internal pressure of the power storage device is equal to or lower than the first pressure), current flows in parallel through both the first conductive paths 18A and the second conductive paths 18B. In the first conductive paths 18A, the path length between the first region 14A and the second region 14B is short, and the electrical resistance is low. On the other hand, in the second conductive paths 18B, in which slits 17 restrict the direction of current flow, and a bent conductive path is formed, the conductive path is long, and in general, the electrical resistance is high.

For example, the electrical resistance of the first conductive parts 15A may be lower than the electrical resistance of the second conductive part 15B. The difference between the first conductive paths 18A and the second conductive paths 18B is whether or not they pass through the first conductive part 15A or the second conductive part 15B on the way from the second region 14B to the first region 14A, and the other route is approximately the same. Therefore, when the electrical resistance of the first conductive parts 15A is lower than that of the second conductive part 15B, the electrical resistance of the first conductive paths 18A is lower than that of the second conductive paths 18B. Furthermore, in the state where the first conductive parts 15A have not broken, current flows in parallel through both the first conductive paths 18A and the second conductive paths 18B, but in the state where the first conductive parts 15A have broken, current flows through the second conductive paths 18B only. Therefore, by comparing the electrical resistance of the current collecting plate 14 in the state where the first conductive parts 15A have not broken to that of the current collecting plate 14 after breakage, the relationship between the electrical resistance of the first conductive parts 15A and the electrical resistance of the second conductive part 15B can be known. When the electrical resistance of the current collecting plate 14 in the state where the first conductive parts 15A have not broken is lower than that of the current collecting plate 14 after breakage, it can be said that the electrical resistance of the first conductive parts 15A is lower than that of the second conductive part 15B.

When the internal pressure of the power storage device increases, the current collecting plate 14 is subjected to a deformation such that the side near the center protrudes more on the first principal surface S1 side than the outer periphery side and bulges. At this time, since the power storage element is joined to the current collecting plate 14 at the second regions 14B provided in the outer peripheral portion of the current collecting plate 14, in a power storage device using the conventional current collecting plate, the joint with the current collector may be partially peeled off, along with the deformation of the second region. However, in a power storage device using the current collecting plate of the present embodiment, the breakage of the first conductive parts occurs as the internal pressure rises, which makes it possible to suppress the peeling-off of the joint between the power storage element and the current collecting plate.

FIG. 2 is an oblique view of the current collecting plate 14, as viewed from the first principal surface side (the surface opposite to the surface where a joint with the power storage element is formed), when the internal pressure of the power storage device in the case exceeds the first pressure, and the first conductive parts 15A have broken. In association with the breakage of the first conductive parts 15A, the second conductive part 15B deforms (elastically or plastically), and the current collecting plate deforms such that the first region 14A protrudes toward the external terminal (so as to move away from the power storage element). At this time, the deformation of the second region 14B is suppressed, suppressing the peeling-off of the joint between the power storage element and the current collecting plate in the second region 14B.

The first pressure may be lower than the valve operating pressure at which the explosion-proof mechanism of the power storage device is activated. The first pressure may be controlled to be a desired pressure by partially thinning the film thickness of the first conductive part 15A, to form a thin-walled portion.

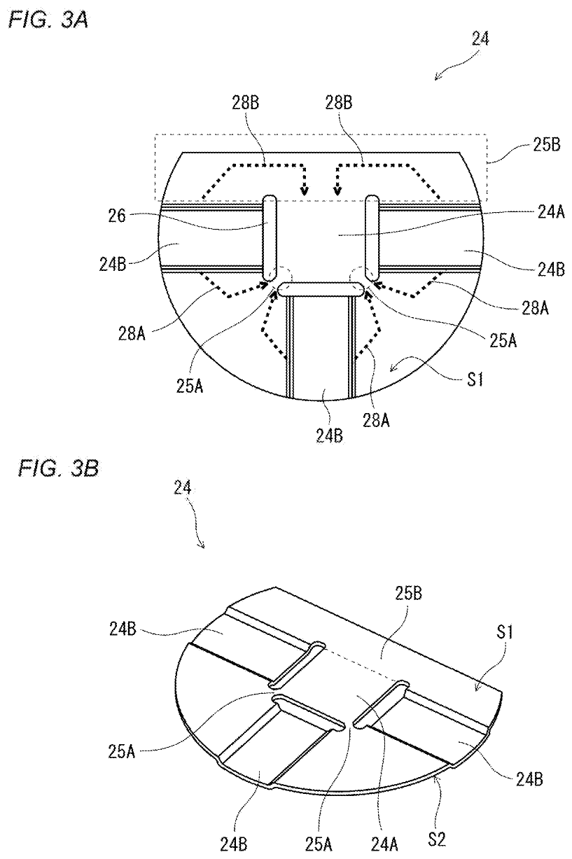

FIGS. 3A and 3B show another example of the configuration of a current collecting plate according to an embodiment of the present disclosure. FIG. 3A is a top view showing the appearance of a current collecting plate 24, and FIG. 3B is an oblique view of the current collecting plate 24 as viewed from the first principal surface side (the surface opposite to the surface where a joint with the power storage element is formed). In a preferred embodiment, the current collecting plate 24 is disposed between the power storage element and the bottom of the case, and can be used to electrically connect the other one of the electrodes (second electrode) of the power storage element to the case. The current collecting plate 24 may be a second current collecting plate or a negative electrode current collecting plate.

The current collecting plate 24 corresponds to the current collecting plate 14 with a changed configuration of the second conductive part 15B. For the configuration of the current collecting plate 24 other than the second conductive part, since it is the same as that of the current collecting plate 14, the description will be omitted or simplified. As long as no technical contradiction arises, part of the configuration of the current collecting plate 14 may be applied to the current collecting plate 24.

The current collecting plate 24, like the current collecting plate 14, has a first region 24A in the central portion thereof, and has a second region 24B in the outer peripheral portion outside the first region 24A. The first region 24A is electrically connected to an external terminal that the sealing member or the case has, on the first principal surface S1 side. The second region 24B is joined to the power storage element on the second principal surface S2 side.

The first conductive parts 25A and the second conductive part 25B each link between the first region 24A and the second region 24B. In the example of FIGS. 3A and 3B, the first conductive parts 15A are each a region sandwiched between the lengthwise ends of a plurality of slits 26 formed along the contour of the first region 14A.

The first conductive parts 25A form first conductive paths 28A linking between the first region 24A and the second region 24B, and the second conductive part 25B forms second conductive paths 28B linking between the first region 24A and the second region 24B. The first conductive paths 28A and the second conductive paths 28B each independently form a current flow path. In the first conductive paths 28A, the path length between the first region 24A and the second region 24B is short, and the electrical resistance is low. On the other hand, in the second conductive paths 28B, the path length is long, and in general, the electrical resistance is high.

FIG. 4 is an oblique view of the current collecting plate 24, as viewed from the first principal surface side (the surface opposite to the surface where a joint with the power storage element is formed), when the internal pressure of the power storage device exceeds the first pressure, and the first conductive parts 25A have broken. In association with the breakage of the first conductive parts 25A, the second conductive part 25B deforms (elastically or plastically), and the current collecting plate deforms such that the first region 24A protrudes toward the external terminal (so as to move away from the power storage element). At this time, the deformation of the second regions 24B is suppressed, suppressing the peeling-off of the joint between the power storage element and the current collecting plate in the second regions 24B.

On the other hand, as compared with the current collecting plate 14, in the current collecting plate 24, because of the difference in the shape of the second conductive part (specifically, the absence of the slits 17), the rigidity of the second conductive part 25B when the first conductive parts have broken is higher than that of the second conductive part 15B in the current collecting plate 14, and the second conductive part 25B hardly deforms. Therefore, the second conductive part acts as a spring against vibrations in the axial direction, suppressing the power storage element from vibrating within the power storage device. The spring constant of the current collecting plate 24 against vibrations in the axial direction when the first conductive parts have broken is greater than that of the current collecting plate 14 against vibrations in the axial direction when the first conductive parts have broken. When using the current collecting plates 14 and 24 in a power storage device, it is preferable to place the current collecting plate 14 with a smaller spring constant on the side facing the sealing member, and place the current collecting plate 24 with a larger spring constant on the side facing the bottom of the case.

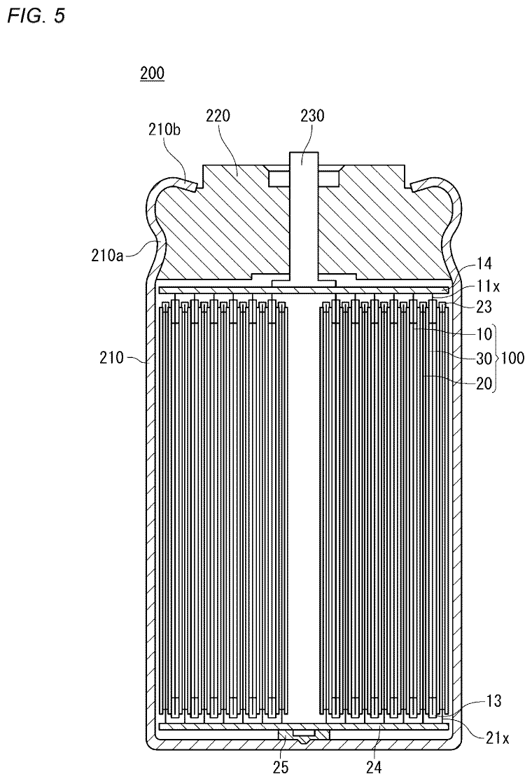

FIG. 5 is a longitudinal sectional view showing the configuration of a power storage device (lithium-ion secondary battery) 200, with the above-described current collecting plates 14 and 24 placed therein.

The power storage device 200 includes a wound element (power storage element) 100 formed into a columnar shape by winding a positive electrode 10 and a negative electrode 20 with a separator 30 interposed therebetween, a nonaqueous electrolyte (not shown), a bottomed metal case 210 housing the wound element 100 and the nonaqueous electrolyte, a sealing rubber 220 sealing the opening of the case 210, the current collecting plate 14, and a terminal 230. The sealing rubber and the terminal 230 constitute a sealing member.

The sealing rubber 220 has a through-hole in the center, and the terminal 230 is inserted into the through-hole. One end of the terminal 230 is electrically connected to the current collecting plate (positive electrode current collecting plate) 14. The other end of the terminal 230 is exposed outside the battery 200 and functions as an external terminal of the battery 200 (in the example of FIG. 5, an external positive terminal).

The sealing rubber 220 is pressed via a side portion (tubular portion) 210a of the case 210, and the opening end of the case 210 is crimped onto the sealing rubber 220, so that the inside of the case 210 is airtightly closed. The crimping forms a curled portion 210b at the opening end of the case 210.

The power storage device 200 can be manufactured by housing the wound element, the current collecting plate, and the sealing rubber in a stacked state in this order inside the case, and then, crimping the opening end of the case onto the sealing rubber, to seal the opening of the case. The manufacturing process therefore can be simplified.

In the power storage device 200, the opening of the case 210 is sealed using a sealing member including the sealing rubber 220 and the terminal 230 inserted to pass therethrough. At this time, one end of the terminal 230 may be welded to the current collecting plate (positive electrode current collecting plate) 14 in the first region 14A, so that the terminal 230 is electrically connected at the one end to the current collecting plate (positive electrode current collecting plate) 14. The method of sealing the opening of the case 210 is not limited to the above example, and a sealing plate that functions as an external terminal and a gasket covering the outer periphery of the sealing plate may be used. In this case, the method of electrically connecting the sealing plate and the current collector is not particularly limited, and the first region of the current collecting plate may be directly connected to the sealing plate or may be connected via an internal lead.

The nonaqueous electrolyte has lithium ion conductivity and contains a lithium salt and a nonaqueous solvent for dissolving the lithium salt.

The positive electrode 10 is in the form of a long sheet and includes a positive electrode current collector and a positive electrode active material layer supported thereon. The positive electrode active material layer is formed on both sides of the positive electrode current collector. A positive electrode current collector-exposed portion 11x without the positive electrode active material layer may be formed at one end along the longitudinal direction of the positive electrode current collector. The positive electrode current collector-exposed portion 11x is exposed on one end face of the wound element 100, and the positive electrode is electrically connected to the current collecting plate 14 via the positive electrode current collector-exposed portion 11x. The positive electrode current collector-exposed portion 11x is connected to the current collecting plate 14 by, for example, welding. On the other hand, the other end along the longitudinal direction of the positive electrode current collector is covered with an insulating layer 13.

The negative electrode 20 is in the form of a long sheet and includes a negative electrode current collector and a negative electrode active material layer supported thereon. The negative electrode active material layer is formed on both sides of the negative electrode current collector. At one end of the negative electrode current collector along the longitudinal direction (the end opposite to the positive electrode current collector-exposed portion 11x), a negative electrode current collector-exposed portion 21x without the negative electrode active material layer is formed. The negative electrode current collector-exposed portion 21x is exposed on the other end face of the wound element 100, and the negative electrode is electrically connected to the current collecting plate (negative electrode current collecting plate) 24 via the negative electrode current collector-exposed portion 21x. The negative electrode current collector-exposed portion 21x is connected to the current collecting plate 24 by, for example, welding. On the other hand, the other end of the negative electrode current collector along the longitudinal direction is covered with an insulating layer 23. The current collecting plate 24 is welded to a welding member 25 provided on the inner bottom surface of the case 210. Thus, the case 210 functions as an external negative electrode terminal.

### (Sealing Rubber)

By using a rubber material as the sealing member, a stable sealing repulsive force is obtained, leading to improved sealing performance of the power storage device. In addition, since a protrusion is constituted of a rubber material, the protrusion can deform when coming in contact with the current collector and subjected to pressure, and can absorb the component tolerances and the assembly tolerance. The sealing rubber having a protrusion can be manufactured by, for example, a molding technique, such as compression molding.

A rubber material, on the other hand, deforms easily with an increase in the internal pressure. Therefore, the rigidity may become insufficient for suppressing bulging. In order to improve the rigidity of the sealing rubber and achieve both high sealing repulsive force and suppression of bulging, the sealing rubber may have a laminated structure having at least two layers of a rubber material layer (e.g., a butyl rubber layer) and a fluorocarbon resin layer. In this case, the protrusion is provided on the rubber material layer.

Although depending on the ambient temperature, the Young's modulus of the rubber material layer may be in the range of 4 MPa to 80 MPa. In contrast, the Young's modulus of the fluorocarbon resin may be 0.4 GPa or more as a general value.

The sealing rubber may be constituted of a single layer of a rubber material layer containing a rubber material, or may have a multilayer structure of a rubber material layer and a fluorocarbon resin layer. Preferred as the rubber material is butyl rubber (isobutylene-isoprene copolymer) (IIR). With butyl rubber, which exhibits stable elasticity through peroxide crosslinking or resin crosslinking, the sealing repulsive force can be stably obtained. With butyl rubber, which has low gas permeability and high insulating properties as compared to other rubber materials, the performance of the power storage device can be maintained high even during a long term storage.

Preferred example of the material of the fluorocarbon resin layer are PTFE (polytetrafluoroethylene), PVDF (polyvinylidene fluoride), PFA (perfluoroalkoxyalkane), ETFE (ethylene-tetrafluoroethylene copolymer), and FEP (perfluoroethylene-propene copolymer). In forming a multilayer structure of a butyl rubber layer and a fluorocarbon resin layer, in order to improve the adhesion at the interface with the rubber material layer, it is preferable to roughen the surface of the fluorocarbon resin layer on the side facing the butyl rubber layer by means of, for example, corona treatment, plasma treatment, sodium treatment, or application of an organic solvent with active sodium dissolved therein, and perform compression molding in the state where the adhesion with the butyl rubber layer has been improved.

### (Current Collecting Plate)

The material constituting the current collecting plate is determined according to the material constituting the positive electrode and the negative electrode. For example, when used as a negative electrode current collecting plate of a lithium-ion secondary battery, the material of the current collecting plate is, for example, copper, copper alloy, nickel, stainless steel, etc. The material of the negative electrode current collecting plate may be the same as the material of the negative electrode current collector. For example, when used as a positive electrode current collecting plate of a lithium-ion secondary battery, the material of the current collecting plate is, for example, aluminum, aluminum alloy, titanium, stainless steel, etc. The material of the positive electrode current collecting plate may be the same as the material of the positive electrode current collector.

The current collector-exposed portion and the current collecting plate can be joined together by, for example, laser welding. The laser may be irradiated radially at a plurality of points from, for example, the side opposite to the surface of the current collecting plate facing the end face of the wound element (i.e., the side facing the sealing rubber).

### (Positive Electrode)

For the positive electrode current collector, a sheet of metal material is used. The sheet of metal material may be a metal foil, a metal porous body, an etched metal, and the like. The metal material may be aluminum, aluminum alloy, nickel, titanium, and the like. The thickness of the positive electrode current collector is, for example, 10 μm to 100 μm.

The positive electrode active material layer includes, for example, a positive electrode active material, a conductive material, and a binder. The positive electrode active material layer is obtained by, for example, applying a positive electrode mixture slurry including a positive electrode active material, a conductive material, and a binder, onto both sides of a positive electrode current collector, and drying the applied film, followed by rolling. The positive electrode active material is a material that absorbs and releases lithium ions. Examples of the positive electrode active material include a lithium-containing transition metal oxide, a transition metal fluoride, a polyanion, a fluorinated polyanion, and a transition metal sulfide.

When the power storage device is a capacitor, such as a lithium-ion capacitor and an electric double layer capacitor, the positive electrode active material layer may contain a positive electrode active material which is to be reversibly doped with anions. When anions are adsorbed onto the positive electrode active material, an electric double layer is formed, to exhibit capacity. The positive electrode may be a polarizable electrode, or may be an electrode which has the properties of a polarizable electrode and in which the Faradaic reaction also contributes to its capacity. The positive electrode active material is, for example, a carbon material, a conductive polymer, and the like.

The conductive polymer is preferably a n-conjugated polymer. As the T-conjugated polymer, for example, polypyrrole, polythiophene, polyfuran, polyaniline, polythiophene vinylene, polypyridine, or a derivative thereof can be used. These may be used singly or in combination of two or more. The weight average molecular weight of the conductive polymer is, for example, 1000 to 100,000. The derivative of a n-conjugated polymer means a polymer whose basic backbone is a n-conjugated polymer, such as polypyrrole, polythiophene, polyfuran, polyaniline, polythiophene vinylene, and polypyridine. For example, a polythiophene derivative includes poly (3,4-ethylenedioxythiophene) (PEDOT).

The carbon material is preferably a porous carbon material, preferable examples of which include an activated carbon and the carbon materials exemplified as the negative electrode active material (e.g., non-graphitizable carbon). Examples of the raw material of the activated carbon include wood, coconut shell, coal, pitch, and phenolic resin. The activated carbon is preferably one that has been subjected to an activation treatment.

### (Negative Electrode)

For the negative electrode current collector, a sheet of metal material is used. The sheet of metal material may be a metal foil, a metal porous body, an etched metal, and the like. The metal material may be copper, copper alloy, nickel, stainless steel, and the like. The thickness of the negative electrode current collector is, for example, 10 μm to 100 μm.

The negative electrode active material layer includes, for example, a negative electrode active material, a conductive material, and a binder. The negative electrode active material layer is obtained by, for example, applying a negative electrode mixture slurry including a negative electrode active material, a conductive material, and a binder, onto both sides of a negative electrode current collector, and drying the applied film, followed by rolling. The negative electrode active material is a material that absorbs and releases lithium ions. Examples of the negative electrode active material include a carbon material, a metal compound, an alloy, and a ceramic material. Examples of the carbon material include graphite and hard carbon.

### (Separator)

The separator may be, for example, a microporous film, a woven fabric, a nonwoven fabric, etc. made of a resin such as polyolefin. The thickness of the separator is, for example, 10 to 300 μm, and preferably 10 to 40 μm.

### (Nonaqueous Electrolyte)

The nonaqueous electrolyte has lithium-ion conductivity and contains a lithium salt and a nonaqueous solvent that dissolves the lithium salt.

### [State Detection Method for Power Storage Device]

A state detection method for a power storage device according to an embodiment of the present disclosure detects, in the above-described power storage device, the state of the power storage device by detecting a change in electrical characteristics of the power storage device caused by the breakage of the first conductive part. The electrical characteristics of the current collecting plate change before and after the breakage of the first conductive part, and the electrical characteristics of the power storage device also change. By measuring this change in electrical characteristics, it is possible to know whether the first conductive part has broken or not, that is, whether an event has occurred or not that causes an increase in the internal pressure in the case of the power storage device, without disassembling the device.

As the electrical characteristics to be measured, the electrical resistance is exemplified. The state detection method for a power storage device may detect the state of the power storage device by detecting a change in internal resistance of the power storage device caused by the breakage of the first conductive part.

In addition, in a state in which the first conductive part has broken, as shown in FIG. 1A, for example, current flows through the bent second conductive paths 18B to the current collecting plate 14, and accordingly, the inductance or capacitance tends to increase. The state detection method for a power storage device may detect the state of the power storage device by detecting a change in inductance or capacitance of the power storage device caused by the breakage of the first conductive part. Also, the state detection method for a power storage device may detect a change in impedance of the power storage device caused by the breakage of the first conductive part. In this case, impedance measurement may be performed, with an AC voltage applied to the power storage device.

### <<Supplementary Notes>

The above description of embodiments discloses the following techniques.

### (Technique 1)

A power storage device, comprising:
a power storage element;
a case having a bottomed cylindrical shape with an opening at one end, and housing the power storage element;
a sealing member sealing the opening; and
a current collecting plate, wherein
the current collecting plate has
a first region electrically connected to an external terminal that the sealing member or the case has,
a second region joined to the power storage element,
at least one first conductive part linking the first region to the second region, and
at least one second conductive part linking the first region to the second region, and
an electrical resistance of the first conductive part is different from an electrical resistance of the second conductive part.

### (Technique 2)

The power storage device according to technique 1, wherein the electrical resistance of the first conductive part is lower than the electrical resistance of the second conductive part.

### (Technique 3)

The power storage device according to technique 1 or 2, wherein a length of the first conductive part is shorter than a length of the second conductive part.

### (Technique 4)

The power storage device according to any one of techniques 1 to 3, wherein a minimum width of the first conductive part is narrower than a minimum width of the second conductive part.

### (Technique 5)

The power storage device according to any one of techniques 1 to 4, wherein, when an internal pressure in the case exceeds a predetermined first pressure, at least one of the at least one first conductive part of the current collecting plate breaks, and the second conductive part remains unbroken.

### (Technique 6)

The power storage device according to technique 5, wherein, when the internal pressure exceeds the first pressure, in association with the breakage of the first conductive part, the second conductive part deforms such that the first region protrudes toward the external terminal in an axial direction of the case.

### (Technique 7)

The power storage device according to any one of techniques 1 to 6, wherein
a plurality of slits are intermittently formed along a contour of the first region, and
the first conductive part has a minimum width sandwiched between lengthwise ends of the plurality of slits.

### (Technique 8)

The power storage device according to any one of techniques 1 to 7, wherein
the first region includes a central portion of the current collecting plate, and
the second region is provided in an outer peripheral portion outside the central portion.

### (Technique 9)

The power storage device according to any one of techniques 1 to 8, wherein
the first region is electrically connected to a terminal portion of the sealing member, and
the second region is joined to a first electrode of the power storage element.

### (Technique 10)

The power storage device according to technique 9, wherein the first region is joined to the terminal portion by welding.

### (Technique 11)

The power storage device according to any one of techniques 1 to 10, wherein
the first region is electrically connected to the case, and
the second region is joined to a second electrode of the power storage element.

### (Technique 12)

The power storage device according to any one of techniques 1 to 11, comprising
a pair of the current collecting plates, wherein
in a first current collecting plate which is one of the pair of the current collecting plates, the first region is electrically connected to the terminal portion of the sealing member, and the second region is joined to a first electrode of the power storage element, and
in a second current collecting plate which is the other one of the pair of the current collecting plates, the first region is electrically connected to the case, and the second region is joined to a second electrode of the power storage element.

### (Technique 13)

The power storage device according to technique 12, wherein the first current collecting plate and the second current collecting plate are different in a shape of at least one of the first conductive part and the second conductive part.

### (Technique 14)

The power storage device according to technique 12 or 13, wherein a spring constant of the second current collecting plate against vibrations in an axial direction of the case when the first conductive part has broken is greater than a spring constant of the first current collecting plate against vibrations in the axial direction when the first conductive part has broken.

### (Technique 15)

A power storage device, comprising:
a power storage element;
a case having a bottomed cylindrical shape with an opening at one end, and housing the power storage element;
a sealing member sealing the opening; and
a current collecting plate, wherein
the current collecting plate has
a first region electrically connected to an external terminal that the sealing member or the case has,
a second region joined to the power storage element,
at least one first conductive part linking the first region to the second region, and
at least one second conductive part linking the first region to the second region, and
when an internal pressure in the case exceeds a predetermined first pressure, at least part of the first conductive part of the current collecting plate breaks, and the second conductive part remains unbroken.

### (Technique 16)

A state detection method for a power storage device, the method comprising,
in the power storage device according to any one of techniques 1 to 15,
detecting a state of the power storage device by detecting a change in electrical characteristics of the power storage device caused by the breakage of the first conductive part.

### (Technique 17)

The state detection method for a power storage device according to technique 16, wherein the state of the power storage device is detected by detecting a change in internal resistance of the power storage device caused by the breakage of the first conductive part.

### INDUSTRIAL APPLICABILITY

The power storage device according to the present disclosure can realize high output, and therefore is suitable for in-vehicle use, for example.

Although the present invention has been described in terms of the presently preferred embodiments, it is to be understood that such disclosure is not to be interpreted as limiting. Various alterations and modifications will no doubt become apparent to those skilled in the art to which the present invention pertains, after having read the above disclosure. Accordingly, it is intended that the appended claims be interpreted as covering all alterations and modifications as fall within the true spirit and scope of the invention.

### REFERENCE SIGNS LIST

100: wound element (power storage element)
   10: positive electrode
      11x: positive electrode current collector-exposed portion
      13: insulating layer
   14: current collecting plate (positive electrode current collecting plate)
      14A: first region
      14B: second region
      15A: first conductive part
      15B: second conductive part
      16, 17: slit
      18A: first conductive path
      18B: second conductive path
   20: negative electrode
      21x: negative electrode current collector-exposed portion
      23: insulating layer
   24: current collecting plate (negative electrode current collecting plate)
      24A: first region
      24B: second region
      25A: first conductive part
      25B: second conductive part
      26: slit
      28A: first conductive path
      28B: second conductive path
   30: separator
200: power storage device
   210: case
      210a: side portion
      210b: curled portion
   220: sealing rubber
   230: terminal

1. A power storage device, comprising:
a power storage element;
a case having a bottomed cylindrical shape with an opening at one end, and housing the power storage element;
a sealing member sealing the opening; and
a current collecting plate, wherein
the current collecting plate has
a first region electrically connected to an external terminal that the sealing member or the case has,
a second region joined to the power storage element,
at least one first conductive part linking the first region to the second region, and
at least one second conductive part linking the first region to the second region, and
an electrical resistance of the first conductive part is different from an electrical resistance of the second conductive part.

2. The power storage device according to claim 1, wherein the electrical resistance of the first conductive part is lower than the electrical resistance of the second conductive part.

3. The power storage device according to claim 1, wherein a length of the first conductive part is shorter than a length of the second conductive part.

4. The power storage device according to claim 1, wherein a minimum width of the first conductive part is narrower than a minimum width of the second conductive part.

5. The power storage device according to claim 1, wherein, when an internal pressure in the case exceeds a predetermined first pressure, at least one of the at least one first conductive part of the current collecting plate breaks, and the second conductive part remains unbroken.

6. The power storage device according to claim 5, wherein, when the internal pressure exceeds the first pressure, in association with the breakage of the first conductive part, the second conductive part deforms such that the first region protrudes toward the external terminal in an axial direction of the case.

7. The power storage device according to claim 1, wherein
a plurality of slits are intermittently formed along a contour of the first region, and
the first conductive part has a minimum width sandwiched between lengthwise ends of the plurality of slits.

8. The power storage device according to claim 1, wherein
the first region includes a central portion of the current collecting plate, and
the second region is provided in an outer peripheral portion outside the central portion.

9. The power storage device according to claim 1, wherein
the first region is electrically connected to a terminal portion of the sealing member, and
the second region is joined to a first electrode of the power storage element.

10. The power storage device according to claim 9, wherein the first region is joined to the terminal portion by welding.

11. The power storage device according to claim 1, wherein
the first region is electrically connected to the case, and
the second region is joined to a second electrode of the power storage element.

12. The power storage device according to claim 1, comprising
a pair of the current collecting plates, wherein
in a first current collecting plate which is one of the pair of the current collecting plates, the first region is electrically connected to the terminal portion of the sealing member, and the second region is joined to a first electrode of the power storage element, and
in a second current collecting plate which is the other one of the pair of the current collecting plates, the first region is electrically connected to the case, and the second region is joined to a second electrode of the power storage element.

13. The power storage device according to claim 12, wherein the first current collecting plate and the second current collecting plate are different in a shape of at least one of the first conductive part and the second conductive part.

14. The power storage device according to claim 12, wherein a spring constant of the second current collecting plate against vibrations in an axial direction of the case when the first conductive part has broken is greater than a spring constant of the first current collecting plate against vibrations in the axial direction when the first conductive part has broken.

15. A power storage device, comprising:
a power storage element;
a case having a bottomed cylindrical shape with an opening at one end, and housing the power storage element;
a sealing member sealing the opening; and
a current collecting plate, wherein
the current collecting plate has
a first region electrically connected to an external terminal that the sealing member or the case has,
a second region joined to the power storage element,
at least one first conductive part linking the first region to the second region, and
at least one second conductive part linking the first region to the second region, and
when an internal pressure in the case exceeds a predetermined first pressure, at least part of the first conductive part of the current collecting plate breaks, and the second conductive part remains unbroken.

16. A state detection method for a power storage device, the method comprising,
in the power storage device according to claim 1,
detecting a state of the power storage device by detecting a change in electrical characteristics of the power storage device caused by the breakage of the first conductive part.

17. The state detection method for a power storage device according to claim 16, wherein the state of the power storage device is detected by detecting a change in internal resistance of the power storage device caused by the breakage of the first conductive part.
